(19) United States
(12) Patent Application Publication
(10) Pub. No.: US 2007/0181816 A1
(43) Pub. Date: Aug. 9, 2007

(54) ANISOTROPIC CONDUCTIVE FILM, X-RAY FLAT PANEL DETECTOR, INFRARED FLAT PANEL DETECTOR AND DISPLAY DEVICE

(75) Inventors: Mitsushi Ikeda, Minato-ku, Tokyo (JP); Toshiyuki Oka, Minato-ku, Tokyo (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/669,299

(22) Filed: Jan. 31, 2007

(30) Foreign Application Priority Data
Jan. 31, 2006 (JP) P2006-023805

(51) Int. Cl. G01T 1/24; H01L 27/14; H01L 25/00; G01J 5/20; H01L 27/146

(52) U.S. Cl. 250/370.14; 250/370.09; 250/338.4; 250/332

(57) ABSTRACT

An anisotropic conductive film includes: an insulating material; and a plurality of conductive particles dispersed in the insulating material, the conductive particles provided in a plurality of lines in a first direction along the thickness of the insulating material, the conductive particles in the lines disposed electrically connectable to each other, and the conductive particles in different lines disposed apart from each other in a second direction perpendicular to the first direction.

### CROSS-REFERENCE TO RELATED APPLICATIONS

This application is based upon and claims the benefit of priority from Japanese Patent Application No. 2006-023805, filed on Jan. 31, 2006, the entire contents of which are incorporated herein by reference.

### BACKGROUND

1. Field

The present invention relates to an anisotropic conductive film, an X-ray flat panel detector, an infrared flat panel detector and a display device.

2. Description of the Related Art

There has been an anisotropic conductive film (ACF) which is conductive in a thickness direction but is insulating in a surface direction perpendicular to the thickness direction. This anisotropic conductive film is provided interposed between a number of terminals or materials to make electrical connection therebetween as well as bonding and fixing thereof. At present, an anisotropic conductive film which exhibits a good electrical conductivity while maintaining its adhesion has been desired. Such an anisotropic conductive film is used for image detectors, image display devices, etc.

As an anisotropic conductive film, there is disclosed an anisotropic conductive film including surface layers containing a phosphoric compound-free layer having no phosphoric compound incorporated in an adhesive resin composition and an interlayer composed of a phosphoric compound-containing layer having a phosphoric compound incorporated in the adhesive resin composition disposed interposed therebetween (see, e.g., JP-A 2005-120220 (KOKAI)). There is also disclosed an anisotropic conductive film including a porous film containing a polymer having a number of pores extending in the thickness direction and aligned in honeycomb pattern, the inner surface of which pores being curved outward, and a conductive layer covering the inner side of the porous film (see, e.g., JP-A 2005-285536 (KOKAI)).

These anisotropic conductive films are used for image detectors for detecting two-dimensional images, for example (see, e.g., JP-A 11-274448 (KOKAI)). These devices are used for the purpose of detecting and imaging X-rays, visible light, infrared rays, etc.

Among these image detectors, X-ray flat panel detectors for use in the art of medicine in particular (see, e.g., U.S. Pat. 4,689,487) have been desired to output image data with a higher resolution for accurate medical treatment of patients. At the same time, the provision of anisotropic conductive films having a higher electrical conductivity has been desired.

This X-ray flat panel detector includes pixels each of which contains an a-Si TFT (amorphous silicon thin-film-transistor), a photoelectric conversion film and a pixel capacitor. These pixels are aligned in a number of hundreds to thousands in array along the longitudinal and crosswise sides.

A bias voltage from en electric supply is applied to the photoelectric conversion film. The a-Si TFT is connected to the signal line and the scanning line. ON/OFF control is made by a scanning line drive circuit. The end of the signal line is connected to an amplifier for signal detection via a switching device.

When light is incident on the X-ray flat panel detector, electric current flows in the photoelectric conversion film to cause charge to be stored in the pixel capacitor. When the scanning line drive circuit drives the scanning line to make all TFT's connected to one scanning line ON, the charge stored in the pixel capacitor is then transferred to the amplifier via the signal line. With the action of the switching device, charge is inputted to the amplifier every one pixel. The charge is then sequentially converted to signal that can be displayed on CRT, etc. The amount of charge differs with the amount of light incident on the pixel. Thus, the amplitude of output varies with the amount of charge inputted.

In such a system, the output signal of the amplifier can be subjected to A/D conversion to make direct digital image display. Further, the pixel region has the same configuration as that of thin film transistor liquid crystal display (hereinafter referred to as “TFT-LCD”) for use in laptop computers, allowing easy production of thin X-ray flat panel detector having a large screen.

In the foregoing description, reference has been made to X-ray flat panel detector of indirect conversion type. The detector of this type operates by converting incident X-rays to visible light by a fluorescent substance or the like, and then allowing the visible light to pass through the photoelectric conversion film of pixels so that it is converted to charge. However, in the X-ray flat panel detector of indirect conversion type, the deterioration of resolution may occur when X-rays are incident on the fluorescent substance, because of scattering the visible light converted from X-rays in the medium constituting the fluorescent substance.

As opposed to this X-ray flat panel detector of indirect conversion type, there is an X-ray flat panel detector which allows direct conversion of X-rays incident on the pixel to charge. This X-ray flat panel detector of direct conversion type is different from the X-ray flat panel detector of indirect conversion type in that X-rays are directly converted to charge in an X-ray charge converting film and the charge is then stored in a pixel capacitor. In other words, the X-ray flat panel detector of direct conversion type has the same configuration as that of the X-ray flat panel detector of indirect conversion type except that the X-ray flat panel detector of direct conversion type is free of fluorescent substance.

This X-ray flat panel detector of direct conversion type includes a storage capacitor containing a laminate of a capacitor electrode, an insulating layer and an auxiliary electrode and a switching TFT and a protective TFT connected to the storage capacitor formed on a glass substrate. On these members is formed a protective film in which a contact hole is formed over the auxiliary electrode. On the protective film are laminated a pixel electrode (connected to the auxiliary electrode through the contact hole), an X-ray charge converting film and a common electrode (upper electrode) in this order. The pixels thus formed are aligned in array.

When X-rays are incident on the X-ray flat panel detector, they are then converted to charge in the X-ray charge converting film. The charge thus generated is then accelerated by an electric field applied between the common electrode and the pixel electrode so that it is stored in the storage capacitor. The switching TFT is driven via a scanning line to transfer the charge stored in the storage capacitor to the signal line. The protective TFT acts to release the charge so that the voltage applied falls below the breakdown voltage when excess charge is generated. This X-ray flat panel detector of direct conversion type does not include a fluorescent substance and allows the X-ray charge converting film to convert X-rays directly to signal charge. As a result, this X-ray flat panel detector of direct conversion type is free from the deterioration of resolution due to scattering of visible light as in the X-ray flat panel detector of indirect conversion type.

However, the signal charge generated by X-rays must be readily passed to the pixel electrode and stored in the storage capacitor. When some signal charge remains in the X-ray charge converting film, the previous image pattern remains as an image lag, which may lead to the occurrence of image defects such as deterioration of resolution. These image defects are attributed mostly to the effect of signal charge remaining in the X-ray charge converting film on the running of signal charge generated by subsequent incidence of X-rays. Further, when the X-ray charge converting film has many defects, electric current flows through these defects to give much dark current.

The X-ray charge converting film is formed by a metal halide such as PbI₂, HgI₂ and BiI₃. In particular, since PbI₂ has a high X-ray absorption coefficient and a high X-ray absorption efficiency, PbI₂ can be expected to exhibit excellent material properties to provide a high conversion efficiency with a thin film. These materials are used in a polycrystalline or monocrystalline form. However, when these materials are used in the form of thin film, they exhibit an insufficient crystallinity that may leads to an image lag, defective resolution and high dark current, etc. Thus, it is the status quo that no films having sufficient properties have been realized (see, e.g., R. A. et al., SPIE Vol. 3659, p. 36, 1999).

Moreover, an insulating film is formed on the underlying electrode for insulating from the upper photosensitive film. A hole is formed in the insulating film for contact at which a great difference in level is produced. The X-ray-sensitive film formed at this area differs from the flat area in growth orientation and thus shows deterioration in crystallinity and hence in X-ray sensitivity. Further, a film peeling or the like may occur at the area having a difference in level. When the pixel electrode is thick, an area having a great slope is produced at the end of the electrode. In order to improve the properties of the X-ray-sensitive film at the area having a difference in level, it is necessary that the underlying substrate be flattened.

As mentioned above, the formation of good quality X-ray charge converting film has never been realized. Further, due to difference in level between X-ray charge converting film and substrate, rough surface and mismatching of film quality with substrate, deterioration of properties of X-ray-sensitive film and peeling of X-ray-sensitive film have occurred. Thus, it has been made difficult to avoid an image lag, defective resolution and high dark current, etc.

### SUMMARY

According to a first aspect of the invention, an anisotropic conductive film includes: an insulating material; and a plurality of conductive particles dispersed in the insulating material, the conductive particles provided in a plurality of lines in a first direction substantially along the thickness of the insulating material, the conductive particles in the lines disposed electrically connectable to each other, and the conductive particles in different lines disposed apart from each other in a second direction substantially perpendicular to the first direction.

According to a second aspect of the invention, an X-ray flat panel detector includes: an X-ray charge converting film converting incident X-ray into charge; pixel electrodes provided on a first surface of the X-ray charge converting film in correspondence to a plurality of pixels aligned in array, respectively; switching elements connected to the pixel electrodes, respectively; signal lines connected to the switching elements, respectively; a scanning line transmitting a drive signal to the switching elements; a common electrode provided on a second surface of the X-ray charge converting film opposite the first surface; and an anisotropic conductive film provided interposed between the X-ray charge converting film and the pixel electrodes, the anisotropic conductive film comprising an insulating material and a plurality of conductive particles dispersed in the insulating material, the conductive particles provided in a plurality of lines in a first direction substantially along which the X-ray charge converting film and the pixel electrodes are opposed to each other, the conductive particles in the lines disposed electrically connectable to each other, and the conductive particles in different lines disposed apart from each other in a second direction substantially perpendicular to the first direction.

According to a third aspect of the invention, an infrared flat panel detector includes: an Infrared charge converting film converting incident infrared rays into charge; pixel electrodes provided on a first surface of the infrared charge converting film in correspondence to a plurality of pixels aligned in array, respectively; switching elements connected to the pixel electrodes, respectively; signal lines connected to the switching elements, respectively; a scanning line for transmitting a drive signal to the switching elements; a common electrode provided on a second surface of the infrared charge converting film opposite the first surface; and an anisotropic conductive film provided interposed between the infrared charge converting film and the pixel electrodes, the anisotropic conductive film comprising an insulating material and a plurality of conductive particles dispersed in the insulating material, the conductive particles provided in a plurality of lines in a first direction substantially along which the infrared charge converting film and the pixel electrodes are opposed to each other, the conductive particles in the lines disposed electrically connectable to each other, and the conductive particles in different lines disposed apart from each other in a second direction substantially perpendicular to the first direction.

According to a fourth aspect of the invention, a display device comprising: an image display layer for displaying an image; pixel electrodes provided on a first surface of the image display layer in correspondence to a plurality of pixels aligned in array, respectively; switching elements connected to the pixel electrodes, respectively; signal lines connected to the switching elements, respectively; a scanning line for transmitting a drive signal to the switching elements; a common electrode provided on a second surface of the image display layer opposite the first surface; and an anisotropic conductive film provided interposed between the pixel electrodes and the switching elements, the anisotropic conductive film comprising an insulating material and a plurality of conductive particles dispersed in the insulating material, the conductive particles provided in a plurality of lines in a first direction substantially along which the switching elements and the pixel electrodes are opposed to each other, the conductive particles in the lines disposed electrically connectable to each other, and the conductive particles in different lines disposed apart from each other in a second direction substantially perpendicular to the first direction.

### BRIEF DESCRIPTION OF THE DRAWINGS

FIG. 1 is a sectional view diagrammatically illustrating the configuration of an anisotropic conductive film according to a first embodiment;

FIG. 2 is a plan circuit diagram illustrating an X-ray flat panel detector including an anisotropic conductive film according to a second embodiment;

FIG. 3 is a plan view of an X-ray flat panel detector of the second embodiment;

FIG. 4 is a sectional view taken along the I-I direction of FIG. 3;

FIG. 5 is an enlarged sectional view of the region αof FIG. 4;

FIG. 6 is a sectional view diagrammatically illustrating how C surface is formed in an X-ray charge converting film free of anisotropic conductive film;

FIG. 7 is a plan circuit diagram illustrating an infrared flat panel detector according to a third embodiment;

FIG. 8 is a plan view of an infrared flat panel detector of the third embodiment;

FIG. 9 is a sectional view taken along the II-II direction of FIG. 8;

FIG. 10 is an enlarged sectional view of the region αof FIG. 9;

FIG. 11 is a plan circuit diagram illustrating the display device including an anisotropic conductive film according to a fourth embodiment;

FIG. 12 is a plan view illustrating of the display device of the fourth embodiment;

FIG. 13 is a sectional view taken along the III-III direction of FIG. 12;

FIG. 14 is an enlarged sectional view of the region αof FIG. 13;

FIG. 15 is a plan circuit diagram illustrating the display device including an anisotropic conductive film according to a fifth embodiment;

FIG. 16 is a sectional view taken along the III-III direction of FIG. 12; and

FIG. 17 is an enlarged sectional view of the region αof FIG. 16.

### DETAILED DESCRIPTION

Embodiments of the invention will be described hereinafter with reference to the drawings. In the following drawings, where the parts are the same or similar, the same or similar numerals are used. However, since these drawings are only diagrammatic, it should be noted that the relationship between thickness and planar dimension, thickness ratio of various layers, etc. are different from actual ones. Accordingly, the actual thickness and dimension should be judged taking into account the following description. It goes without saying that dimensional relationship and ratio differ from drawing to drawing.

### FIRST EMBODIMENT

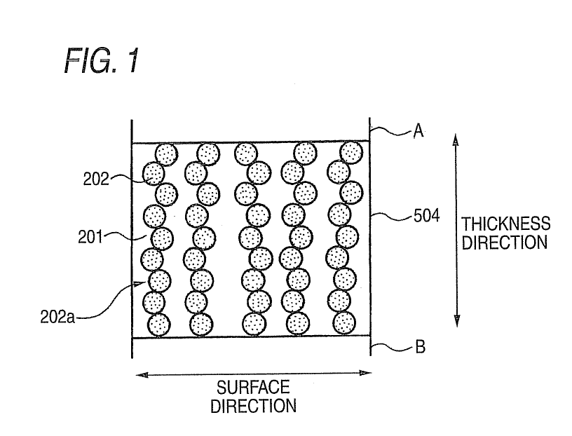

A first embodiment of the invention will be described hereinafter with reference to FIG. 1.

As shown in FIG. 1, an anisotropic conductive film 504 includes an insulating material 201 and conductive particles 202 dispersed in the insulating material 201. Further, the conductive particles 202 are disposed in a plurality of conductive particle lines 202a in the direction of the thickness constituting the anisotropic conductive film 504 wherein the conductive particles 202 in each of the conductive particle lines 202a are disposed electrically connectable to each other and the conductive particles 202 are disposed apart from each other in the surface direction perpendicular to the thickness direction.

In this arrangement, the anisotropic conductive film 504 has a high electrical conductivity in the thickness direction but a very high resistivity or high electrical insulation in the surface direction.

As the insulating material 201 to be used herein, there may be used an organic resin such as PVA (polyvinyl alcohol), acryl, polyethylene, polycarbonate, polyimide and polyetherimide or an inorganic material such as polysilazane.

Each of the conductive particles 202 contains, e.g., pigment, particulate carbon, particulate metal, ITO (indium tin oxide) or the like.

The conductive particles 202 are preferably formed by conductive nano-particles having a diameter on the nanometer order, preferably from 10 nm to 500 nm, more preferably from 50 nm to 100 nm. In the case where the conductive particles 202 have a diameter on the order of micrometer or more, it is necessary that the volumetric percentage of the conductive particles 202 contained in the anisotropic conductive film 504 be reduced such that the conductive particles 202 are disposed apart from each other in the direction substantially along the surface of the anisotropic conductive film 504 in order to render the anisotropic conductive film 504 anisotropic in electrical conductivity. However, as the volumetric percentage of the conductive particles 202 lowers, the electrical conductivity of the conductive particles in the thickness direction lowers.

The conductive particles 202 in each of the conductive particle lines 202a substantially along the thickness direction preferably come in contact with each other. When the conductive particles 202 come in contact with each other, a higher electrical conductivity in the thickness direction can be obtained.

The conductive particles 202 in the surface direction are preferably insulated from each other. When the conductive particles 202 in the surface direction are thus insulated from each other, charge generated in a material A can be uniformly conducted to an electrode material B connected to the underlying storage capacitor or the like in parallel to each other without the aid of the thickness-direction electrical conductivity as shown in FIG. 1.

Thus, the anisotropic conductive film 504 contains conductive particles 202 disposed electrically connectable to each other in a plurality of electrical particle lines 202a in the thickness direction. In this arrangement, the conductive particles can be dispersed in the anisotropic conductive film 504 in a greater amount. Further, the conductive particles 202 are disposed apart from each other in the surface direction substantially perpendicular to the thickness direction. Thus, the anisotropic conductive film 504 has a high resistivity in the surface direction. In this arrangement, the anisotropic conductive film 504 can be provided with a drastically enhanced electrical conductivity in the thickness direction as well as a high resistivity in the surface direction.

Each of the anisotropic conductive films disclosed in JP-A 11-274448 (KOKAI) has a metallic electrode disposed above and under an anisotropic conductive film, which upper and lower electrodes being connected to each other with one conductive particle. In this arrangement, when there is no upper electrode interposed between the anisotropic conductive film and the upper photosensitive film, electrical connection can be established only by a partial region having conductive particles present therein, making it impossible to establish electrical connection between the photosensitive film and the anisotropic conductive film within a required range. Thus, in order to increase the conductive area within the required range, an electrode needs to be disposed above and under the anisotropic conductive film. On the other hand, in the anisotropic conductive film 504, the diameter of the conductive particles is sufficiently smaller than the distance between the upper and lower electrodes. Further, the conductive particles are disposed in a plurality of lines. In this arrangement, even when one of the aforementioned upper and lower electrodes is absent, the other existing electrode can be electrically connected to the overlying photosensitive film in the area where it has been directly transferred. Accordingly, when the anisotropic conductive film 504 is used, one of the aforementioned upper and lower electrodes can be omitted, making it possible to simplify the process of manufacturing an X-ray flat panel detector, an infrared flat panel detector, a display device and other devices described later and reduce the production cost.

### SECOND EMBODIMENT

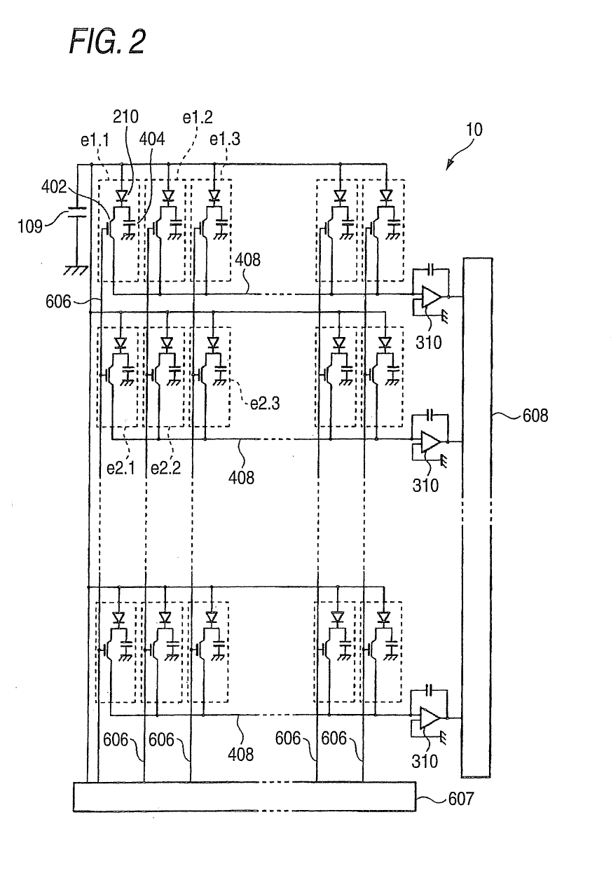

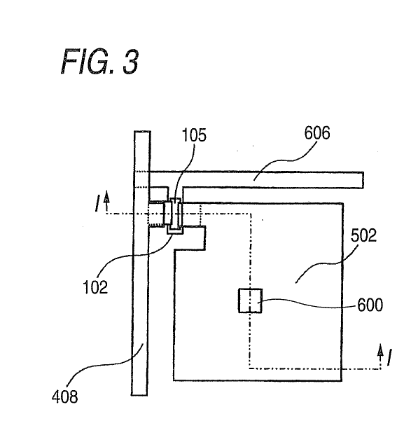

A second embodiment of the invention will be described hereinafter with reference to FIGS. 2 to 5. In FIG. 3, a protective film 107, a pixel electrode 503, an anisotropic conductive film 504, an X-ray charge converting film 210 and an upper electrode 212 are not shown for the convenience of description.

As shown in FIG. 2, an X-ray flat panel detector 10 includes a plurality of pixels ei.j (j=1, 2, . . . ) aligned in matrix manner. Each pixel ei.j has a switching TFT 402, an X-ray charge converting film 210 and a storage capacitor 404.

A negative bias voltage from an electric supply 109 is applied to the X-ray charge converting film 210. The switching TFT 402 is connected to a signal line 408 and a scanning line 606. ON/OFF control is made by a scanning line drive circuit 607. The end of the signal line 408 is connected to a shift register 608 via an amplifier 310.

When X-rays are incident on the X-ray flat panel detector, positive holes and electrons are generated in the X-ray charge converting film 210. The electrons are stored in the storage capacitor 404 for a while. The scanning lines 606 are driven by the scanning line drive circuit 607. When the switching TFT 402 in a line connected to one of the scanning lines 606 is switched ON, the signal charge stored in the storage capacitor 404 is transferred via the signal line 408 to the amplifier 310 where it is then amplified. The signal charge thus amplified is sequentially read out by the shift register 608, and then outputted to the exterior. The amount of charge generated depends on the amount of light incident on the pixel. Thus, the amplitude of output of the amplifier 310 varies with the amount of charge thus generated. The output of the amplifier 310 corresponds to brightness.

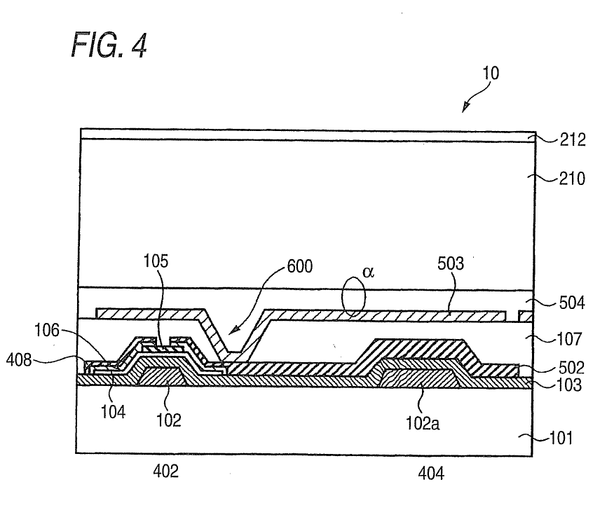

As shown in FIGS. 3 and 4, the anisotropic conductive film 504 of the first embodiment is applied to the X-ray flat panel detector 10. The X-ray flat panel detector 10 includes a gate electrode 102 for switching TFT 402 (hereinafter simply referred to as “TFT”), a scanning line 606, an electrode 102a for the storage capacitor 404 and a storage capacitor line (not shown) formed on a glass substrate 101. The gate electrode 102 for TFT 402, the scanning line 606, the electrode 102a for the storage capacitor 404 and the storage capacitor line are formed by, e.g., one layer of a material selected from the group essentially consisting of molybdenum-tantalum (MoTa), tantalum (Ta), tantalum nitride (TaNx), aluminum (Al), Al alloy, copper (Cu) and molybdenum-tungsten (MoW) or two layers respectively containing tantalum (Ta) and tantalum nitride (TaNx).

On the glass substrate 101, an insulating film 103 formed, as well as the gate electrode 102 for TFT 402 and the electrode 102a for the storage capacitor 404. The insulating film l03 contains, e.g., silicon oxide (SiOx) or silicon nitride (SiNx) or a laminate of silicon oxide (SiOx) and silicon nitride (SiNx).

An undoped amorphous silicon layer 104 (hereinafter referred to as “a-Si layer”) is formed, as a back gate region for TFT 402, on the gate electrode 102 for TFT 402 via the insulating film 103. The a-Si layer 104 has a convex upward portion that reflects the shape of the gate electrode 102. On the top of the convex portion of the a-Si layer 104 is, e.g., a stopper 105 containing silicon nitride that defines a source/drain region for switching TFT 402.

On the a-Si layer 104, an amorphous silicon layer 106 doped with high concentration n-type impurities (hereinafter referred to as “n⁺ a-Si layer”) is formed as a source/drain region for TFT 402. The n⁺ a-Si layer 106 defines a source/drain region with the open portion thus formed and the stopper 105.

On the n⁺ a-Si layer 106 and the insulating film 103, an auxiliary electrode 502 and a signal line 408 are formed and electrically connected with the n⁺ a-Si layer 106. The auxiliary electrode 502 and the signal line 408 contain, e.g., a laminate of Mo and Al. The auxiliary electrode 502 is formed at the same layer as the signal line 408 and the source and drain for TFT 402 from the structural point of view.

Further, the protective film 107 is formed on the auxiliary electrode 502. The protective film 107 includes, e.g., a laminate of silicon nitride and acrylic organic resin film. An organic film containing BCB (benzocyclobuten), PI (polyimide) or the like may be used instead of acrylic resin. The organic film preferably has a heat resistance temperature of 200 degrees C. or more. The term “heat resistance temperature” as used herein is meant to indicate a lowest temperature at which thermal decomposition occurs.

A contact hole 600 is provided in the protective film 107 at which the surface of the auxiliary electrode 502 is exposed. A pixel electrode 503 is formed on the protective film 107 containing the contact hole 107 and is electrically connected to the auxiliary electrode 502. The pixel electrode 503 contains, e.g., ITO film. The ITO film may be amorphous or polycrystalline.

An anisotropic conductive film 504 is formed on and to cover the pixel electrode 503. The anisotropic conductive film 504 is formed to fill the contact hole 600 and has a flattened surface.

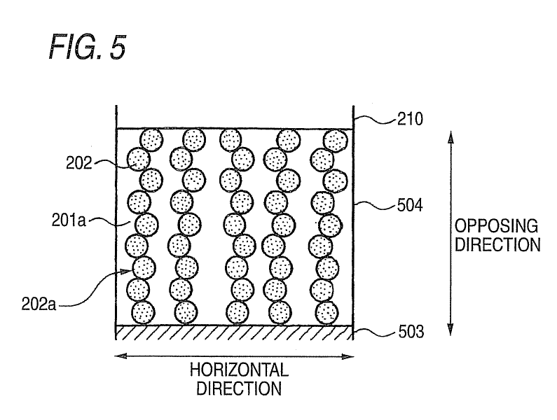

The anisotropic conductive film 504 includes an insulating organic material 201a having insulating properties and a plurality of conductive particles 202 dispersed in the insulating organic material 201a as shown in FIG. 5.

The conductive particles 202 are disposed in a plurality of conductive particle lines 202a in the direction substantially along which the X-ray charge converting film 210 described later and the pixel electrode 503 are opposed to each other. The conductive particles 202 in each of the conductive particle lines 202a are disposed electrically connectable to each other.

In the anisotropic conductive film 504, the conductive particles 202 are disposed apart from each other in the direction substantially perpendicular to the direction along which the X-ray charge converting film 210 described later and the pixel electrode 503 are opposed to each other (hereinafter referred to as “horizontal direction”). In this arrangement, the anisotropic conductive film 504 has a high resistivity or is electrically insulated in the horizontal direction.

The insulating organic material 201a contains an insulating plastic organic resin having a thermal expansion coefficient close to that of the material constituting the X-ray charge converting film 210 described later. Examples of such an organic material include PVA, acryl, polyethylene, polycarbonate, polyimide, and polyetherimide. As the acryl there may be used CKB (produced by Fuji Film Arch), Optomer HRC (produced by JSR) or the like.

The conductive particles 202 is preferably formed by conductive nano-particles having a diameter on the nanometer order, preferably from 10 nm to 500 nm, more preferably from 50 nm to 100 nm. In the case where each conductive particle 202 has a diameter on the order of micrometer or more, it is necessary that the volumetric percentage of the conductive particles 202 contained in the anisotropic conductive film 504 be reduced such that the conductive particles 202 don't come in contact with each other in the horizontal direction of the anisotropic conductive film 504 in order to render the anisotropic conductive film 504 anisotropic in electrical conductivity. However, as the volumetric percentage of the conductive particles 202 lowers, the electrical connection of the X-ray charge converting film 210 described later to the anisotropic conductive film 504 is established only at a region where the conductive particles 202 are present, making it difficult to establish electrical connection of the X-ray charge converting film 210 to the anisotropic conductive film 504 in the region required to obtain X-ray photograph. The conductive particle 202 contains, e.g., pigment, particulate carbon, particulate metal, ITO or the like.

The volumetric percentage of the conductive particles 202 in the entire anisotropic conductive film 504 is preferably from 20% to 45%. When the volumetric percentage of the conductive particles 202 in the entire anisotropic conductive film 504 falls below 20%, the electrical connection of the X-ray charge converting film 210 described later to the anisotropic conductive film 504 is established only in a region where the conductive particles 202 are present. This makes it difficult to establish electrical connection of the X-ray charge converting film 210 to the anisotropic conductive film 504 in the region required to obtain X-ray photograph. When the volumetric percentage of the conductive particles 202 in the entire anisotropic conductive film 504 exceeds 45%, the conductive particles 202 are contained in the insulating organic material 201a of the anisotropic conductive film 504 more than necessary and thus come in contact with each other also in the horizontal direction of the insulating organic material 201a, rendering the anisotropic conductive film 504 conductive also in the horizontal direction to an extent close to that in the direction along which the X-ray charge converting film 210 and the pixel electrode 503 are opposed to each other. The volumetric percentage of the conductive particles 202 in the entire anisotropic conductive film 504 is more preferably from 25% to 40%.

The anisotropic conductive film 504 preferably has a low resistivity in the aforementioned direction along which the X-ray charge converting film 210 and the pixel electrode 503 are opposed to each other to readily transfer the signal charge generated in the X-ray charge converting film 210 described later to the storage capacitor 404. On the other hand, when the anisotropic conductive film 504 has a low resistivity in the aforementioned horizontal direction, the signal charge is conducted to adjacent pixels, causing signal mixing that deteriorates resolution. Therefore, the anisotropic conductive film 540 preferably has a high resistivity or is insulated in the horizontal direction. In accordance with the embodiment of the invention, when the electrical conductivity in the direction along which the X-ray charge converting film 210 and the pixel electrode 503 are opposed to each other is 10 or more times that in the horizontal direction, improvement can be made.

As mentioned above, the anisotropic conductive film 504 has conductive particles 202 disposed in a plurality of conductive particle lines 202a in the direction along which the X-ray charge converting film 210 described later and the pixel electrode 503 are opposed to each other. The conductive particles 202 in each of the conductive particle lines 202aare disposed electrically connectable to each other. On the other hand, the conductive particles 202 are disposed apart from each other in the direction along which the X-ray charge converting film 210 and the pixel electrode 503 are opposed to each other. In this arrangement, the anisotropic conductive film 504 allows rapid transfer of signal charge generated in the X-ray charge converting film 210 to the storage capacitor 404 disposed opposed to the anisotropic conductive film 504 while preventing the mixing of signal charge from adjacent pixels in the horizontal direction, making it possible to suppress the deterioration of resolution.

The conductive particles 202 in each of the conductive particle lines 202a in the direction along which the X-ray charge converting film 210 and the pixel electrode 503 are opposed to each other preferably come in contact with each other. The arrangement of the conductive particles 202 in contact with each other makes it possible to render the anisotropic conductive film 504 more conductive in the direction along which the X-ray charge converting film 210 and the pixel electrode 503 are opposed to each other.

The conductive particles 202 in the aforementioned horizontal direction are preferably insulated from each other. The arrangement of the conductive particles 202 insulated from each other in the horizontal direction makes it possible to further prevent the mixing of signal charge from adjacent pixels in the horizontal direction.

As previously mentioned, the anisotropic conductive film 504 includes conductive particles having a sufficiently smaller diameter than the distance between the upper and lower electrodes. The conductive particles 202 are disposed in a plurality of conductive particle lines 202a in the direction along which the upper and lower electrodes are opposed to each other. In this arrangement, even when one of the upper and lower electrodes is absent, the other existing electrode can be electrically connected to the overlying photosensitive film in the area where it has been directly transferred. Accordingly, one of the aforementioned upper and lower electrodes can be omitted, making it possible to simplify the process of manufacturing an X-ray flat panel detector and reduce the production cost.

The X-ray charge converting film 210 is provided on the anisotropic conductive film 504 for converting incident X-rays to charge. The X-ray charge converting film 210 contains an X-ray-sensitive material sensitive to X-ray. The X-ray-sensitive material contains a metal halide having a high X-ray charge conversion efficiency. The metal halide is preferably a material having a high X-ray absorption coefficient to provide a high X-ray absorption efficiency. Preferred examples of such a metal halide include chloride, bromide and iodide of at least one metal selected from the group essentially consisting of Pb, Hg, Tl, Bi, Cd, In, Se, Sn and Sb. Preferred among these metals are Pb, Hg and Bi, which have a high X-ray absorption coefficient. In particular, iodides of these metals having a high X-ray absorption coefficient are preferred. These metal halides are hexagonal and have similar lattice constants. These metal halides have a high resistivity and thus allow the flow of lower dark current and hence the detection of small charge signal, making it possible to enhance the performance of the X-ray flat panel detector. Among the aforementioned materials, BiI₃ lacks a part of atoms in the hexagonal structure of iodine but is not so different from the complete hexagonal structure in the effect of lattice matching. The use of a substrate containing materials having similar lattice constants makes it possible to obtain a high quality X-ray charge converting film.

The aforementioned metal halide has a thermal expansion coefficient of from 5×10⁻⁵ to 5×10⁻⁴/° C. which is much higher than that of commonly used glass substrate (5×10⁻⁶/° C.). Therefore, when the aforementioned metal halide is used to obtain a high performance X-ray charge converting film 210, the difference in thermal expansion coefficient between the X-ray charge converting film 210 and the glass substrate 101 causes the occurrence of deflection of glass substrate 101, crack and peeling of X-ray charge converting film 210, etc. An anisotropic conductive film 504 containing PVA, acryl, polyethylene, polycarbonate, polyimide, polyetherimide or the like can be provided interposed between the glass substrate 101 and the X-ray charge converting film 210 to prevent the occurrence of deflection of glass substrate 101, crack and peeling of film, etc. This is because the resins such as PVA, acryl, polyethylene, polycarbonate, polyimide and polyetherimide has a thermal expansion coefficient of from about 3×10⁻⁵ to 10×10⁻⁵/° C. which is almost the same as that of the X-ray charge converting film 210 containing metal halide, making it possible to prevent cracking, peeling, etc. at the interface of the X-ray charge converting film 210 with the anisotropic conductive film 504. Further, these resins have so high a plasticity as to relax the thermal stress caused by the difference in thermal expansion coefficient between the X-ray charge converting film 210 and the glass substrate 101, making it possible to suppress the deflection of the glass substrate 101.

An upper electrode 212 is formed on the X-ray charge converting film 210 for accelerating the charge generated in the X-ray charge converting film 210. The upper electrode 212 contains, e.g., Pd.

A process for manufacturing an X-ray flat panel detector 10 including the anisotropic conductive film according to the embodiment will be described hereinafter with reference to FIGS. 2 to 4.

Firstly, one layer containing metal selected from the group essentially consisting of molybdenum-tantalum (MoTa), tantalum (Ta), tantalum nitride (TaNx), aluminum (Al), Al alloy, copper (Cu) and molybdenum-tungsten (MoW) or two layers containing tantalum (Ta) and tantalum nitride (TaNx), respectively, are deposited on a glass substrate 101 to a thickness of about 300 nm. The deposit is then patterned by etching to form a gate electrode 102 for TFT 402, a scanning line 606, an electrode 102a for the storage capacitor 404 and a storage capacitor line (not shown) on the glass substrate 101.

Subsequently, on the substrate 101 including the gate electrode 102 for TFT 402 and the electrode 102a for the storage capacitor 404, silicon oxide (SiOx) and silicon nitride (SiNx) are deposited to a thickness of about 300 nm and about 50 nm, respectively, by plasma CVD method to form an insulating film 103. Subsequently, plasma CVD is effected to form a first semiconductor layer on the insulating film 103 to a thickness of about 100 nm as a-Si layer 104. Subsequently, a silicon nitride (SiNx) layer is formed on the first semiconductor layer to a thickness of about 200 nm as stopper 105.

The silicon nitride layer thus formed is then patterned by a back side exposure method according to the gate electrode 102 to form a stopper 105. A second semiconductor layer is then deposited on the stopper 105 to a thickness of about 50 nm as n⁺ a-Si layer 106. The first semiconductor layer and the second semiconductor layer are then etched according to the shape of the transistor to form island-shaped a-Si layer 104 and n⁺ a-Si layer 106.

Subsequently, though not shown, the insulating film 103 at the contact area inside and outside the pixel area is etched to form contact holes on which Mo and Al are then deposited by sputtering to a thickness of about 50 nm and about 350 nm, respectively. Mo is then deposited by spattering to a thickness of from about 20 nm to 50 nm. Thus, au auxiliary electrode 502, a signal line 408, a source and drain for TFT 402, and other lines (not shown) are formed.

Thereafter, silicon nitride is deposited to a thickness of about 200 nm covering the auxiliary electrode 502 and the signal line 408. An acrylic organic resin film (Optomer HRC (trade name), produced by JSR) is then deposited on the silicon nitride layer to a thickness of from about 1 μm to 5 μm, preferably about 3.5 μm to form a protective film 107. An organic film of BCB, PI (polyimide) or the like may be used instead of acrylic resin. Such an organic film preferably has a heat resistance temperature of 200 degrees C. or more. The term “heat resistance temperature” as used herein is meant to indicate a lowest temperature at which thermal decomposition occurs.

Subsequently, a contact hole 600 extending to the auxiliary electrode 502 is formed in the protective film 107. The protective film 107 is then subjected to sputtering with ITO (indium tin oxide) as an pixel electrode metal so that an ITO film is deposited thereon to a thickness of about 100 nm. Thereafter, the ITO film is patterned by etching to form a pixel electrode 503. The method for the formation of ITO film is not limited to sputtering but may be effected otherwise, e.g., vacuum metallization. The ITO film to be formed as pixel electrode metal may be amorphous or polycrystalline.

Subsequently, an anisotropic conductive film 504 containing an insulating organic material 201a and a plurality of conductive particles 202 dispersed therein is formed to fill the contact holes 600 in the protective film 107.

In order to form the anisotropic conductive film 504, an acrylic resin as insulating organic material 201a and carbon particles having a particle diameter of from 50 μm to 100 nm as conductive particles 202 are mixed. A solvent such as cyclohexanone is then added to the mixture. The mixed solution thus prepared is spread over the protective film 107, and then annealed at 100 degrees C. to cause the solvent component such as cyclohexanone to evaporate.

For the formation of the anisotropic conductive film 504, the volumetric percentage of the conductive particles 202 in the entire anisotropic conductive film 504 is from 20% to 45%, more preferably from 25% to 40%. By adding a solvent such as cyclohexanone to the mixture in an amount of from 5% to 30%, preferably from 10% to 25% by volume based on the entire anisotropic conductive film 504, spreading the mixed solution over the protective film 107, and then annealing the spread, an anisotropic conductive film 504 can be formed having conductive particles 202 disposed in the insulating organic material 201a in a plurality of conductive particle lines 202ain the direction along which the X-ray charge converting film 210 and the pixel electrode 503 are opposed to each other but apart from each other in the horizontal direction perpendicular to the direction along which the X-ray charge converting film 210 and the pixel electrode 503 are opposed to each other as shown in FIG. 5. As the aforementioned acrylic resin there is used CKB (produced by Fuji Film Arch), Optomer HRC (produced by JSR) or the like. The acrylic resin may be diluted with a solvent such as polymer and cyclohexane before use. The insulating organic material 201a is not limited to acrylic resin and may be PVA, polyethylene, polycarbonate, polyimide, polyetherimide or the like.

Subsequently, an X-ray charge converting film 210 containing PbI₂ is vacuum-deposited on the anisotropic conductive film 504 to a thickness of from about 100 μm to 1,000 μm, preferably 300 μm.

Subsequently, Pd is deposited on the substantially entire surface of the region 1 cm apart from the periphery of the X-ray charge converting film 210 to a thickness of about 200 nm to form an upper electrode 212. A voltage application electrode is then formed on the upper electrode 212. A peripheral drive circuit is then mounted on the TFT array X-ray charge converting film substrate to produce an X-ray flat panel detector 10 as shown in FIG. 2.

An X-ray image was detected using this X-ray flat panel detector 10. As a result, the X-ray flat panel detector 10 was confirmed to have improvements, i.e., enhanced X-ray sensitivity and lowered dark current.

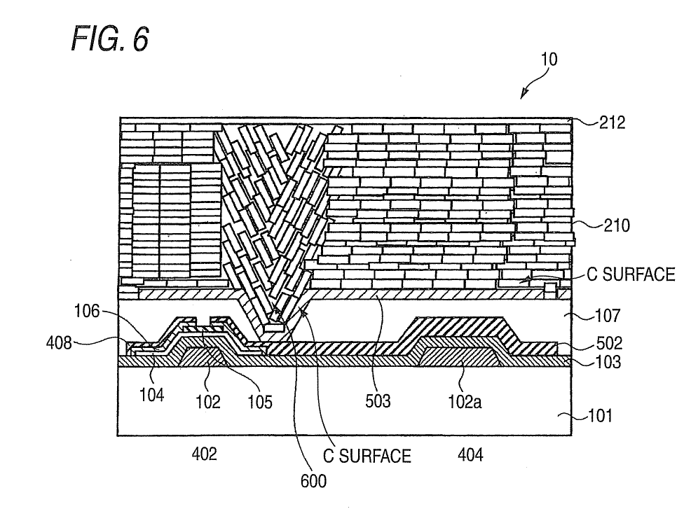

The aforementioned X-ray flat panel detector 10 according to the present embodiment includes an anisotropic conductive film 504 having a flattened surface and some plasticity that fills the contact holes 600 in the protective film 107 and an X-ray charge converting film 210 formed on the flattened surface of the anisotropic conductive film 504. In this arrangement, the X-ray charge converting film 210 can have its crystal face formed parallel to the glass substrate 101. For example, in the case where the X-ray charge converting film 210 contains, e.g., PbI₂ and the anisotropic conductive film 504 is not provided, as shown in FIG. 6, there are two regions, i.e., region where C surface is formed parallel to the glass substrate 101 and region where C surface is formed along the slope of the contact hole 600. Therefore, different crystal faces are formed at the section where two regions cross each other; one of the regions is where C surface is formed parallel to the glass substrate 101 and another of the regions is where c surface is formed along the slope of the contact hole. At this crossing section, crystal boundaries collide with each other. Since there are present crystals having different orientations at this crossing section, there are many crystal boundary defects that cause the rise of dark current and the deterioration of properties such as X-ray sensitivity.

In the embodiment, on the other hand, an anisotropic conductive film 504 having a flattened surface is provided to fill the contact holes 600. An X-ray charge converting film 210 is formed on the surface of the anisotropic conductive film 504. In this arrangement, there are no crystals having different orientations as shown in FIG. 6. No problems such as rise in dark current and deterioration of X-ray sensitivity attributed to the presence of crystals having different orientations arise. The insulating organic material 201a contained in the anisotropic conductive film 504 has a thermal expansion coefficient close to that of the overlying X-ray charge converting film 210 and a high plasticity and thus can relax the thermal stress caused by the difference in thermal expansion coefficient between the glass substrate 101 and the X-ray charge converting film 210. Accordingly, cracking, deflection of substrate and peeling of X-ray charge converting film 210, etc. can be relaxed. Further, since the film quality is little deteriorated on the interface of formation of the X-ray charge converting film 210, an X-ray flat panel detector 10 which is little subject to sensitivity drop and dark current rise can be provided.

### THIRD EMBODIMENT

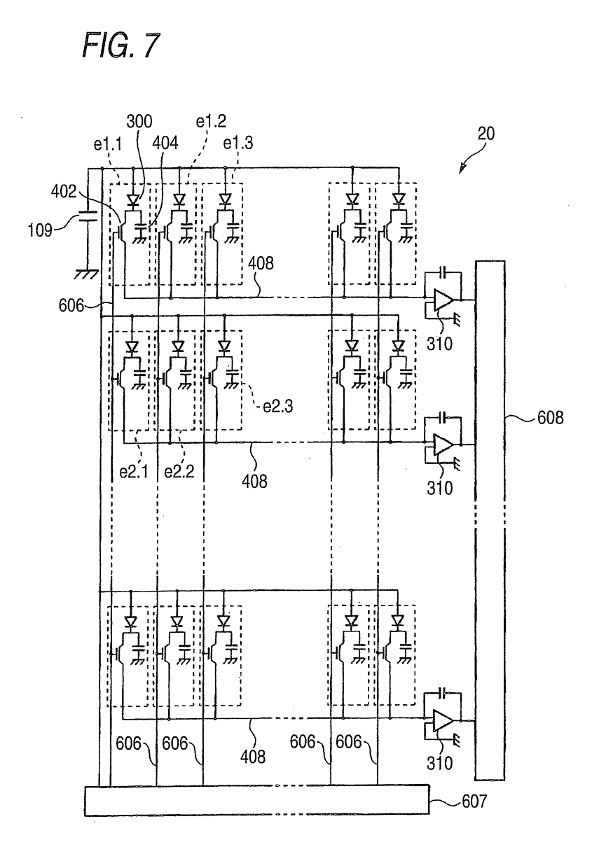

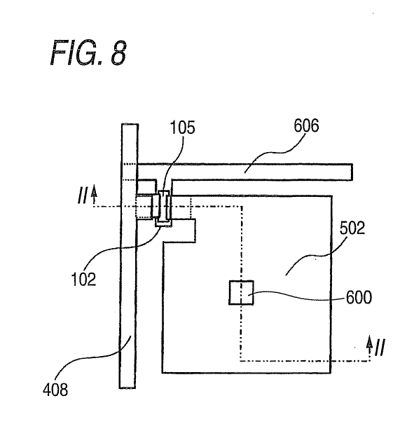

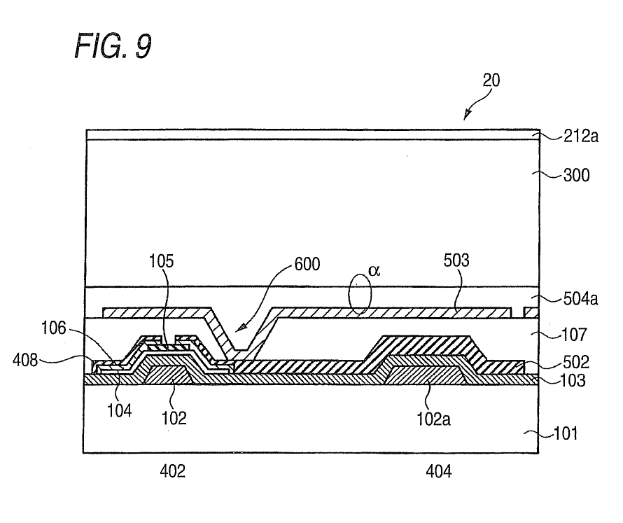

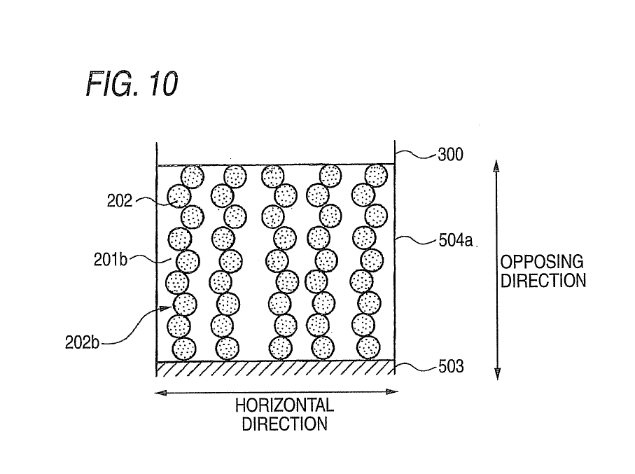

A third embodiment of the invention will described with reference to FIGS. 7 to 10. Where the parts have the same material and configuration as the aforementioned X-ray flat panel detector 10, the same numerals are used.

As shown in FIGS. 7 to 10, the infrared flat panel detector 20 according to the present embodiment is the same as the aforementioned X-ray flat panel detector 10 except that it includes an anisotropic conductive film 504a containing an insulating inorganic material 201b such as polysilazane instead of insulating organic material 201a, the X-ray charge converting film 210 is replaced by an infrared photosensitive film 300 and the upper electrode 212 is replaced by an upper electrode 212a containing In. The other configurations are the same as in the X-ray flat panel detector 10 and thus will not be described.

The insulating organic material 201b contains an inorganic plastic material having insulating properties and a thermal expansion coefficient close to that of the material constituting the infrared photosensitive film 300 described later. As such an inorganic material there may be used a polysilazane or the like.

In order to form the anisotropic conductive film 504a, a polysilazane as insulating organic material 201b and carbon particles having a particle diameter of from 50 nm to 100 nm as conductive particles 202 are mixed. A solvent is then added to the mixture. The mixed solution thus prepared is spread over the protective film 107, and then annealed at 100 degrees C. to cause the solvent component to evaporate.

The infrared-sensitive film 300 incident infrared rays to charge is provided on the anisotropic conductive film 504a for converting incident infrared rays to charge. The infrared-sensitive film 300 contains, e.g., CdSe, CdS, PbS or the like.

The infrared-sensitive film 300 is formed by vacuum-depositing CdSe on the anisotropic conductive film 504a to a thickness of from about 100 μm to 1,000 μm, preferably 300 μm.

The upper electrode 212a is formed on the infrared-sensitive film 300 for accelerating the charge generated in the infrared-sensitive film 300. The upper electrode 212a contains, e.g., In.

In the aforementioned infrared flat panel detector 20 according to the present embodiment, an anisotropic conductive film 504a having a flattened surface and some plasticity is formed to fill the contact holes 600 in the protective film 107. The infrared-sensitive film 300 is formed on the flattened surface of the anisotropic conductive film 504a. In this arrangement, the deterioration of crystallinity of the infrared-sensitive film 300 attributed to the uneven lower shape of the infrared-sensitive film 300 can be prevented.

Further, the insulating inorganic material 201b contained in the anisotropic conductive film 504a has a thermal expansion coefficient close to that of the overlying infrared-sensitive film 300 and thus can relax problems such as cracking and peeling of infrared-sensitive film 300. Further, since the film quality is little deteriorated on the interface of formation of the infrared-sensitive film 300, an infrared flat panel detector 20 which is little subject to sensitivity drop and dark current rise can be provided.

Further, as previously mentioned, the anisotropic conductive film 504a includes conductive particles 202 having a sufficiently smaller diameter than the distance between the upper and lower electrodes. The conductive particles 202 are disposed in a plurality of lines. In this arrangement, even when one of the upper and lower electrodes is absent, the other existing electrode can be electrically connected to the overlying photosensitive film in the area where it has been directly transferred. Accordingly, one of the aforementioned upper and lower electrodes can be omitted, making it possible to simplify the process of manufacturing an infrared flat panel detector and reduce the production cost of the infrared flat panel detector.

### FOURTH EMBODIMENT

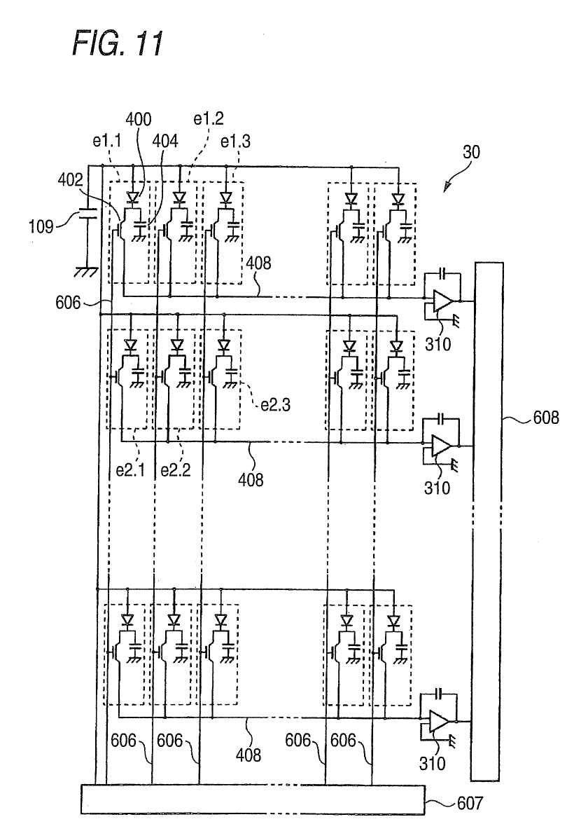

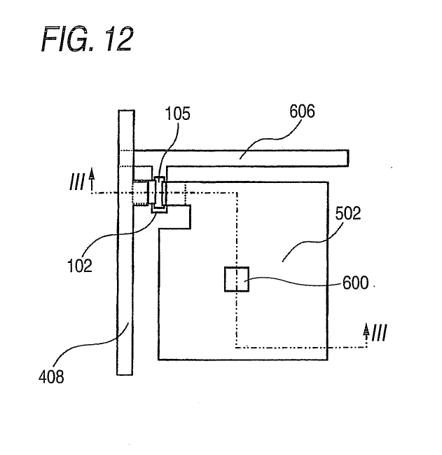

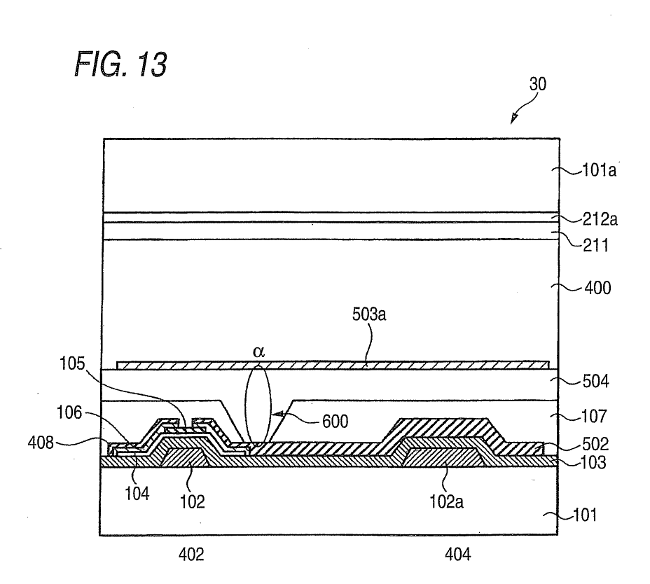

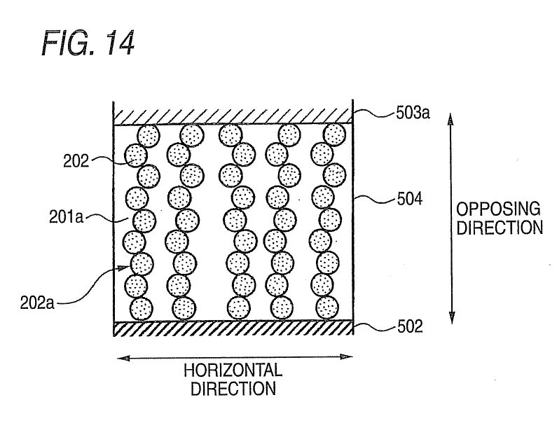

A fourth embodiment of the invention will be described with reference to FIGS. 11 to 14. Where the parts have the same material and configuration as in the aforementioned X-ray flat panel detector 10, the same numerals are used.

The display device 30 according to the present embodiment is the same as the aforementioned X-ray flat panel detector 10 except that the X-ray charge converting film 210 is replaced by a liquid crystal 400, the pixel 503 provided on the protective film 107 is replaced by a pixel electrode 503a provided interposed between the anisotropic conductive film 504 and the liquid crystal 400, the upper electrode 212 is replaced by an upper electrode 212a which is an ITO electrode, an alignment film 211 is provided interposed between the liquid crystal 400 and the upper electrode 212a and an opposite substrate 101a containing the same material as glass substrate 101 is provided on the upper electrode 212a. In the present embodiment, the anisotropic conductive film 504 acts as a conductive film for electrically connecting the upper pixel electrode 503a to the lower auxiliary electrode 502. The anisotropic conductive film also acts to level the surface that forms the pixel electrode 503a.

As the liquid crystal 400 there is used one obtained by rubbing a polyimide for liquid crystal alignment.

The pixel electrode 503a contains, e.g., Al—Pd and thus is so reflective as to reflect incident light beam. In other words, the display device 30 according to the present embodiment is a reflective liquid crystal display device.

The alignment film 211 contains, e.g., a polyimide.

The upper electrode 212a contains, e.g., ITO electrode.

A method for the formation of the pixel electrode 503a, the liquid crystal 400, etc. will be described hereinafter.

The aforementioned anisotropic conductive film 504 is formed to fill the contact holes 600 in the protective film 107 under the aforementioned conditions. The anisotropic conductive film 504 having a flattened surface thus obtained is coated with Al—Pd which is then patterned to form a pixel electrode 503a. Subsequently, a polyimide is deposited on the pixel electrode 503a as liquid crystal 400 to a thickness of about 70 nm. The polyimide film is then subjected to rubbing for liquid crystal. The opposite substrate 101a containing glass substrate is then prepared. An ITO film is then formed on the opposite substrate 101a as upper electrode 212a to a thickness of 500 A. A polyimide is then deposited on the ITO film as alignment film 211 to a thickness of 70 nm. The polyimide film is then subjected to rubbing for liquid crystal. Subsequently, the periphery of the glass substrate 101 and the opposite substrate 101a is sealed with an epoxy resin to enclose the liquid crystal.

The display device 30 thus prepared exhibited such good display properties that no color change of liquid crystal portion due to different in level present at the contact holes 600 occur.

In the aforementioned display device 30 according to the present embodiment, an anisotropic conductive film 504 having a flattened surface is formed to fill the contact holes 600 in the protective film 107. A pixel electrode 503a is formed on the flattened surface of the anisotropic conductive film 504a. In this arrangement, the color change of the liquid crystal portion attributed to the uneven lower shape of the pixel electrode 503a can be prevented.

Further, as previously mentioned, the anisotropic conductive film 504 includes conductive particles 202 having a sufficiently smaller diameter than the distance between the upper and lower electrodes. The conductive particles are disposed in a plurality of lines. In this arrangement, even when one of the upper and lower electrodes is absent, the other existing electrode can be electrically connected to the overlying photosensitive film in the area where it has been directly transferred. Accordingly, one of the aforementioned upper and lower electrodes can be omitted, making it possible to simplify the process of manufacturing a display device and reduce the production cost of the display device.

The aforementioned display device 30 can be applied to transmissive liquid crystal display devices. The transmissive liquid crystal display device can be realized by incorporating ITO in the aforementioned anisotropic conductive film 504 in a proper amount and forming the pixel electrode 503a by ITO.

### FIFTH EMBODIMENT

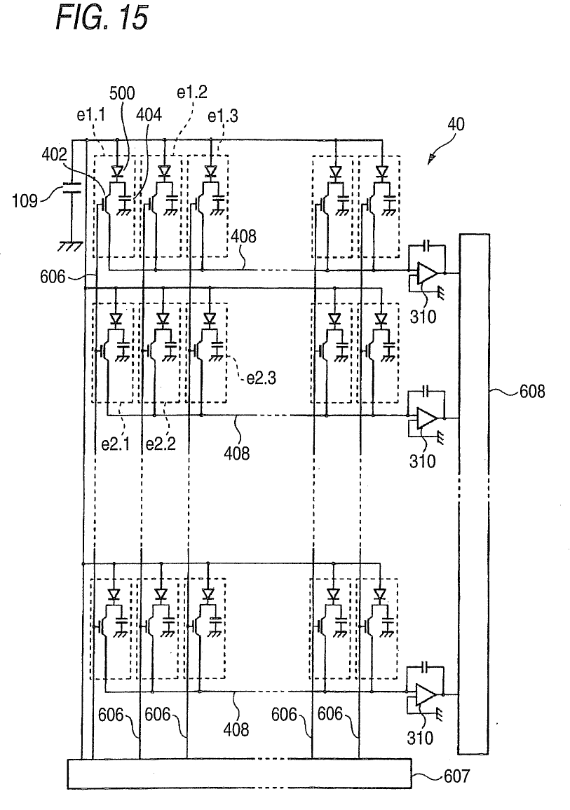

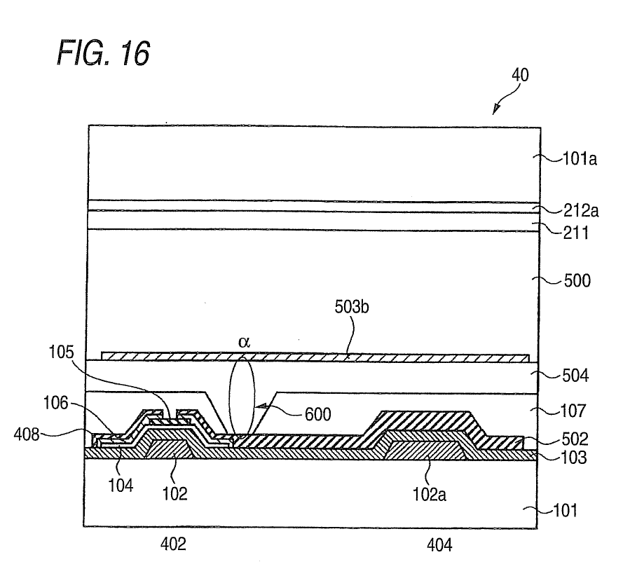

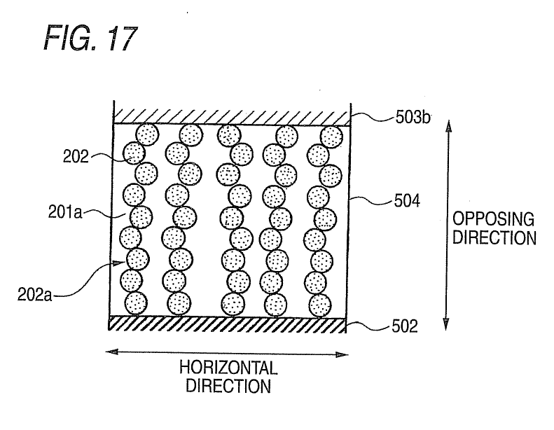

A fifth embodiment of the invention will be described with reference to FIGS. 15 to 17. Where the parts have the same material and configuration as the aforementioned display device 30, the same numerals are used.

The display device 40 according to the present embodiment is the same as the aforementioned display device 30 except that the liquid crystal 400 is replaced by an organic EL (electroluminescent) film 500 and the pixel electrode 503a is replaced by a pixel electrode 503b containing an Al—Mg alloy. The other configurations are the same as in the aforementioned display device 30 and thus will not be described.

The organic EL film 500 contains, e.g., a laminate of CsO₂ layer, Alq3 layer (aluminato-tris-8-hydroxyquinolate (Alq3) and TDP layer.

The pixel electrode 503b contains, e.g., Al—Mg alloy.

A method for the formation of the pixel electrode 503b and the organic EL film 500 will be described hereinafter.

The aforementioned anisotropic conductive film 504 is formed to fill the contact holes 600 in the protective film 107 under the aforementioned conditions. The anisotropic conductive film 504 having a flattened surface thus obtained is coated with Al—Mg alloy which is then patterned to form a pixel electrode 503b. Subsequently, a CS0₂ layer, Alq3 and TPD are deposited on the pixel electrode 503b each to a thickness of 50 nm to form an organic EL film 500.

The display device 40 thus prepared showed no deterioration of performance of organic EL film due to difference in level present in the area of the contact holes 600 and hence good display properties.

In the aforementioned display device 40 according to the present embodiment, an anisotropic conductive film 504 having a flattened surface is formed to fill the contact holes 600 in the protective film 107. A pixel electrode 503b is formed on the flattened surface of the anisotropic conductive film 504. In this arrangement, the color change of the liquid crystal portion attributed to the uneven lower shape of the organic EL film 500 can be prevented.

Further, as previously mentioned, the anisotropic conductive film 504 includes conductive particles 202 having a sufficiently smaller diameter than the distance between the upper and lower electrodes. The conductive particles are disposed in a plurality of lines. In this arrangement, even when one of the upper and lower electrodes is absent, the other existing electrode can be electrically connected to the overlying organic EL film in the area where it has been directly transferred. Accordingly, one of the aforementioned upper and lower electrodes can be omitted, making it possible to simplify the process of manufacturing a display device and reduce the production cost of the display device.

The invention is not limited to the aforementioned various embodiments. The invention can be applied to any planar devices having many pixels. The invention can be more effectively applied to detectors and display devices on active matrix type TFT array. The detective film is not limited to X-ray-sensitive detective film and infrared-sensitive film. The invention can be applied to detectors using visible light, ultraviolet rays, etc. In particular, in the case where the photosensitive detective film is containing a polycrystalline or monocrystalline material, the invention can exert a great leveling effect to advantage. Also, when a photosensitive film containing an amorphous material is used, there occurs no thickness change at areas having a difference in level to advantage. In particular, in the case where a laminate film is used, there occurs no break of thin film at areas having a difference in level or no thickness change to advantage. The base material of the anisotropic conductive film is not limited to organic materials but may be an inorganic insulating material such as SiO₂. As the particulate material for lowering resistivity there may be used any conductive material. An organic material such as pigment or an inorganic conductive particulate material such as particulate metal, particulate carbon and MoOx may be used. As the polymer there may be used any film-forming material. PVA, acryl, polyethylene, polycarbonate, polyimide, polyetherimide or a conductive polymer may be used. As the material to be patterned there is preferably used a photosensitive polymer which can be patterned by exposure through a mask. In order to prevent the deterioration of the performance of overlying functional films such as photosensitive film, organic EL film and liquid crystal due to unevenness caused by the conductive particles, a thin conductive film, an insulating film, etc. may be properly laminated. For example, a pure base polymer or base inorganic material may be formed into a thin film.

The invention is not limited to the aforementioned embodiments. The constitutions of these embodiments may be modified and embodied without departing from the gist of the invention at the step of implementation. The plurality of constitutions disclosed in the aforementioned embodiments can be properly combined to constitute various inventions. For example, some of all the constitutions disclosed in the embodiments can be deleted. Further, the constitutions of different embodiments may be properly combined.

What is claimed is:

1. An anisotropic conductive film comprising:
an insulating material; and
a plurality of conductive particles dispersed in the insulating material, the conductive particles provided in a plurality of lines in a first direction substantially along the thickness of the insulating material, the conductive particles in the lines disposed electrically connectable to each other, and the conductive particles in different lines disposed apart from each other in a second direction substantially perpendicular to the first direction.

2. The film according to claim 1, wherein the conductive particles in the same line come in contact with each other.

3. The film according to claim 2, wherein the conductive particles in the different lines are insulated from each other.

4. The film according to claim 1, wherein the conductive particle is formed by conductive nano-particle having a diameter on the nanometer order.

5. An X-ray flat panel detector comprising:
an X-ray charge converting film converting incident X-ray into charge;
pixel electrodes provided on a first surface of the X-ray charge converting film in correspondence to a plurality of pixels aligned in array, respectively;
switching elements connected to the pixel electrodes, respectively;
signal lines connected to the switching elements, respectively;
a scanning line transmitting a drive signal to the switching elements;
a common electrode provided on a second surface of the X-ray charge converting film opposite the first surface; and
an anisotropic conductive film provided interposed between the X-ray charge converting film and the pixel electrodes, the anisotropic conductive film comprising an insulating material and a plurality of conductive particles dispersed in the insulating material, the conductive particles provided in a plurality of lines in a first direction substantially along which the X-ray charge converting film and the pixel electrodes are opposed to each other, the conductive particles in the lines disposed electrically connectable to each other, and the conductive particles in different lines disposed apart from each other in a second direction substantially perpendicular to the first direction.

6. The detector according to claim 5, wherein the conductive particles in the same line come in contact with each other.

7. The detector according to claim 6, wherein the conductive particles in the different lines are insulated from each other.

8. The detector according to claim 5, wherein the conductive particle is formed by conductive nano-particles having a diameter on the nanometer order.

9. The detector according to claim 5, wherein the X-ray charge converting film contains a chloride, bromide or iodide of at least one metal selected from the group essentially consisting of Pb, Hg, Tl, Bi, Cd, In, Se, Sn and Sb.

10. An infrared flat panel detector comprising:
an Infrared charge converting film converting incident infrared rays into charge;
pixel electrodes provided on a first surface of the infrared charge converting film in correspondence to a plurality of pixels aligned in array, respectively;
switching elements connected to the pixel electrodes, respectively;
signal lines connected to the switching elements, respectively;
a scanning line for transmitting a drive signal to the switching elements;
a common electrode provided on a second surface of the infrared charge converting film opposite the first surface; and
an anisotropic conductive film provided interposed between the infrared charge converting film and the pixel electrodes, the anisotropic conductive film comprising an insulating material and a plurality of conductive particles dispersed in the insulating material, the conductive particles provided in a plurality of lines in a first direction substantially along which the infrared charge converting film and the pixel electrodes are opposed to each other, the conductive particles in the lines disposed electrically connectable to each other, and the conductive particles in different lines disposed apart from each other in a second direction substantially perpendicular to the first direction.

11. A display device comprising:
an image display layer for displaying an image;
pixel electrodes provided on a first surface of the image display layer in correspondence to a plurality of pixels aligned in array, respectively;
switching elements connected to the pixel electrodes, respectively;
signal lines connected to the switching elements, respectively;
a scanning line for transmitting a drive signal to the switching elements;
a common electrode provided on a second surface of the image display layer opposite the first surface; and
an anisotropic conductive film provided interposed between the pixel electrodes and the switching elements, the anisotropic conductive film comprising an insulating material and a plurality of conductive particles dispersed in the insulating material, the conductive particles provided in a plurality of lines in a first direction substantially along which the switching elements and the pixel electrodes are opposed to each other, the conductive particles in the lines disposed electrically connectable to each other, and the conductive particles in different lines disposed apart from each other in a second direction substantially perpendicular to the first direction.

12. The device according to claim 11, wherein the image display layer contains one of a liquid crystal and an organic electroluminescent film.
